(19) United States
(12) Patent Application Publication
(10) Pub. No.: US 2011/0056549 A1
(43) Pub. Date: Mar. 10, 2011

(54) Thin-film solar module and method of making

(76) Inventors: Michael Berginski, Essen (DE); Peter Lechner, Vaterstetten (DE)

(21) Appl. No.: 12/807,240

(22) Filed: Aug. 31, 2010

(30) Foreign Application Priority Data
Sep. 8, 2009 (DE) 10 2009 040 621.2

(51) Int. Cl. H01L 31/0216; H01L 31/18

(52) U.S. Cl. 136/256; 438/63; 257/E31.12

(57) ABSTRACT

In a thin-film solar module comprising a transparent substrate (1), a transparent doped zinc oxide front electrode film (2) deposited on substrate (1), a semiconductor film (3), an optional doped zinc oxide rear electrode film (4), and a reflecting layer (5) on the rear surface turned away from the side of light incidence (hv), the dopant quantities in doped zinc oxide front and/or rear electrode films (2, 4) decrease from substrate (1) towards semiconductor film (3) and from semiconductor film (3) towards reflecting layer (5), respectively.

The invention relates to a thin-film solar module as defined in the pre-characterizing portion of patent claim 1 and to a method of making it.

Thin-film solar modules essentially consist of a transparent, electrically non-conductive substrate, especially of glass, a transparent, electrically conductive front electrode layer or film, a semiconductor layer or film and a reflecting layer of e.g. a single- or multi-layered metal system or of a white dielectric material on the rear surface.

The front electrode film generally consists of doped tin oxide or of zinc oxide doped with boron, gallium or aluminium.

Deposition of the front electrode film on the substrate is carried out mostly by sputtering. To this end are used ceramic zinc oxide (ZnO) sputter targets doped e.g. with aluminium oxide (Al₂O₃) and containing some specific quantity—such as 1 or 2% weight percent—of Al₂O₃. Alternatively, sputtering is carried out reactively from metal zinc aluminium targets. In both cases, the sputtering gas consists of a noble gas and oxygen, the latter especially in the case of reactive sputtering.

A drawback of targets with as much as 2 wt. % Al₂O₃ is the high light absorption of the resultant film. Targets having as little as 1 wt. % Al₂O₃, are disadvantageous in that more than 1000 nm must be sputtered on to obtain the desired sheet resistivity of the deposited film.

Another drawback is that, in the case of a doped ZnO sputter target with 1 wt. % Al₂O₃, the substrate has to be heated in the sputtering process to an elevated temperature higher than 250° C., requiring an expensive machine design, long heating and cooling trips, and high operating costs.

In applications where an electrically non-conductive white dielectric material—such as white paint or a white film—is used as a reflecting layer on the rear surface of the module, another doped zinc oxide or tin oxide layer is sputtered on between that reflecting rear surface layer and the semiconductor layer to a relatively heavy thickness of 200 nm to 3000 nm, for example.

It is the object of the invention to provide a high-quality front electrode film and at the same time, in case the reflecting layer consists of a white material layer, a high-quality rear electrode film while keeping energy and equipment investment as low as possible.

In accordance with the invention, this object is accomplished by the dopant quantity of the doped ZnO front electrode film decreasing from the substrate towards the semiconductor film. Also in accordance with the invention, and in case the thin-film solar module has a white reflecting dielectric material layer and thus a doped zinc oxide rear electrode film, the dopant quantity in the doped ZnO rear electrode film may decrease as well from the semiconductor film towards the reflecting white material layer.

In accordance with the invention, the said decrease from one side towards the other side of the front electrode film or of the rear electrode film may be continuous or step-wise.

In accordance with the invention, the dopant quantity, i.e. the number of foreign doping atoms in the zinc oxide, on the side of the ZnO front electrode film turned towards the substrate and/or the dopant quantity on the side of the ZnO rear electrode film turned towards the semiconductor layer is a maximum of 2×10²¹ cm⁻³, and that dopant quantity is lower than 1×10²¹ cm⁻³, preferably between 4×10²⁰ cm⁻³ and 8×10²⁰ cm⁻³, on the side turned towards the semiconductor layer of the ZnO front electrode film and/or on the side turned towards the reflecting white material layer.

The zinc oxide is doped preferably with aluminium, gallium or boron. Indium, germanium, silicon and fluorine may be used as well. While the aluminium- or gallium-doped ZnO layer is formed preferably by sputtering from ZnO—Al₂O₃ targets or ZnO—Ga₂O₃ targets having different concentrations of Al₂O₃ or Ga₂O₃, respectively, a boron-doped ZnO layer is obtained preferably by low-pressure chemical vapour phase deposition (“LPCVD”), using diborane or trimethylboron for the gaseous boron compound, for example, and by providing a greater quantity of the boron compound at the beginning of the ZnO deposition process than towards its end.

The relationship between the target dopant quantity and the resultant dopant quantity in the electrode film has been examined for Al₂O₃ doped ZnO ceramic targets by Agashe et al. (Journal of Applied Physics, 95, 2004, pp. 1911-1917), for example. In addition to a linear relationship between the target and electrode dopant quantities, these authors found, among other things, that a target dopant quantity of 1.0 wt. % results in electrode films containing approx. 7×10²⁰ cm⁻³ of dopant.

The doped ZnO front electrode film and/or the doped ZnO rear electrode film preferably have a sheet resistivity lower than 24 ohms per square, more preferred lower than 18 ohms per square and, most preferred, lower than 14 ohms per square.

At 700 nm wavelength of the incident light, the light absorption of the front or rear doped ZnO electrode film is lower than 5%, more preferred lower than 4% and most preferred lower than 3.5%; at a wavelength of 950 nm of the incident light, it preferably is lower than 8%, more preferably lower than 7% and most preferably lower than 6%.

Conventionally, the substrate of the inventive thin-film solar module comprises a sheet of glass. The preferred semiconductor layer is silicon, preferably composed of partial layers of microcrystalline or amorphous silicon, for example. The semiconductor layer may comprise a composite semiconductor—e.g. a II-VI semiconductor such as cadmium telluride, a III-V semiconductor such as gallium arsenide or a I-III-VI semiconductor such as copper-indium diselenide.

Preferably, the doped ZnO rear electrode film is at least 300 nm thick; in particular, it is at least 400 nm thick, e.g. 500 nm.

For the ZnO front electrode, a film preferably 500 nm to 5000 nm and especially 1000 nm to 2000 nm thick was initially deposited and then subjected to etching.

On its side facing the semiconductor layer, the front electrode film is provided with a specific surface topography or roughness so as to impart “light trapping” characteristics to it, meaning that light reflected back towards the substrate through the semiconductor layer is reflected back as completely as possible into the semiconductor layer. To this end, the thick doped ZnO semiconductor film deposited on the substrate is subjected to etching using dilute hydrochloric acid, for example, resulting in the formation in the front electrode film on the side thereof facing the semiconductor layer of crater-shaped recesses having a preferred depth of 50 nm to 600 nm and especially of 150 nm to 400 nm, a preferred width of 500 nm to 5000 nm and especially of 800 nm to 3000 nm, and a preferred opening angle of 100° to 150° and especially 110° to 145°. After the etching treatment, the preferred roughness is at least 50 nm r.m.s., especially at least 100 nm r.m.s. Etching these structures will reduce the preferred coating thickness of the front electrode film to at least 20 nm and especially 50 nm to 300 nm at the thinnest parts of the crater-shaped recesses. The front electrode may be etched away to expose the substrate in isolated locations at most.

A sputtering plant is used for sputtering the doped ZnO front and/or rear electrode films. Separate sputtering plants may be used for sputtering the front and rear electrode films.

The one, or each, sputtering plant comprises a feed-in vacuum lock for introducing the substrate, i.e. normally the glass sheet, and a sequence of ZnO sputtering stations each holding a doped ZnO sputter target, as well as one or more heating lines, if any. An additional sputtering station may be provided between the feed-in vacuum lock and the ZnO sputtering stations for the application between the glass substrate and the doped ZnO front electrode of a barrier layer intended to match refractive indexes so as to minimize reflections and to prevent a diffusion of ions such as Na from the glass substrate into the ZnO film. To this end, a sputter target of silicon dioxide (SiO₂) or silicon oxinitride (SiOₓN_{y}) with x>0.1 and x+y=1.5 may be used.

The substrates typically travel along approx. 5 to approx. 10 ZnO sputtering stations to obtain the successive deposition of a doped ZnO film to a total thickness of 1000 nm, for example.

Depositing the ZnO front electrode film preferably uses dual tube cathodes with ceramic ZnO:Al₂O₃ or ZnO:Ga₂O₃ targets, from which pulsed D.C. sputtering is carried out.

In so doing, the ZnO target of the sputter station adjoining the feed-in zone in the deposition plant comprises for sputtering the front electrode film a dopant quantity, i.e. an quantity of the foreign oxide Al₂O₃ or Ga₂O₃, of preferably between 0.9 and 3.1 wt. %, more preferably between 1.1 and 2.5 wt. % and most preferably between 1.5 and 2.1 wt. %, with that dopant quantity of the ZnO sputter targets decreasing towards the discharge zone of the sputtering plant down to a target dopant quantity between preferred 0.2 and 1.5 wt. %, especially between 0.5 and 1.2 wt. % and most preferred between 0.7 and 1 wt. %. In analogy, the ZnO sputter target in the sputtering station adjacent the feed-in zone of the sputtering plant comprises for sputtering the rear electrode film a dopant quantity of preferably between 0.9 and 3.1 wt. %, more preferably between 1.1 and 2.5 wt. % and most preferably between 1.5 and 2.1 wt. %, with the dopant quantity of the ZnO sputter target decreasing towards the discharge zone down to preferably 0.2 to 1.5 wt. %, more preferably between 0.5 to 1.2 wt. % and most preferably to 0.7 to 1.2 wt. %.

These figures relate to a major portion of the ZnO front or rear electrode deposited. They do not take into account additional or a few sputter stations arranged to apply, for example, a ZnO seed layer 2 to 5 nm thick at the beginning of the sputtering line or a refractive index matching layer towards the end of the ZnO front electrode deposition.

For example, the target dopant quantity for the front electrode film may vary as follows:

At the beginning is used a ZnO target with 2 wt. % Al₂O₃, with the quantity of Al₂O₃ subsequently decreasing to 1 wt. % in an intermediate zone and decreasing to a final 0.5 wt. % Al₂O₃ at the discharge zone.

While the ZnO front electrode film is being sputtered, the temperature of the substrate may preferably be up to max. 280° C. in the sputtering station adjoining the discharge zone. Thus, in the above example using an Al₂O₃ doped ZnO target, the required substrate temperature may increase from exemplary 80° C. in the sputtering station adjacent the feed-in zone to approx. 250° C. at the sputtering station adjoining the discharge zone.

In contrast, in sputtering the doped ZnO rear contact layer, the substrate is heated preferably to not more than 180° C. as they semiconductor layer may be damaged by higher temperature levels.

Among others, the invention allows the following advantages to be realized:

As ZnO targets with higher dopant levels such as 0.9 to 3 wt. % allow the desired film properties to be obtained at comparatively low substrate temperatures, portions adjacent the deed-in zone of the sputtering plant may be designed for low process temperatures, and especially for temperatures lower than 200° C., whereby less expensive materials may be used and the capital outlay for the plant is reduced.

The use of more highly doped targets at the beginning of the sputtering line and of the concomitant lower process temperatures—typically below 200° C.—allow the heat-up distance to be shorter, contributing further to reduced investment.

The sputtering treatment itself will increase the substrate temperature. Heating means disposed at the sputtering stations of the sputtering plant may provide for the further controlled heating of the substrates to result in a higher substrate temperature of high foreign-oxide ZnO sputter targets at the end of the sputtering line. It has been found that, in the case of high foreign-oxide sputter targets, the substrate temperature may vary widely without degrading the characteristics of the doped ZnO film; thus the tasks of heating and sputtering, which usually are carried out at spatially separate locations in the sputtering plant, may be concentrated in this part thereof so as to additionally utilize the heating the sputtering process itself contributes.

Despite the proposed reduction of the target dopant quantity along the sputtering line, a preferred embodiment of the invention allows for the sputtering gas or sputtering gas mixture to be selected to be identical in all zinc oxide sputtering stations. This embodiment is preferred because it obviates a gas separation between several sputtering stations.

The material deposited from highly doped targets at the beginning of the sputtering line has a comparatively high charge carrier density of often more than 2×10²⁰ cm⁻³, which enables the required low sheet resistivity to be obtained. If the entire doped ZnO film—e.g. 1000 nm thick—consisted of this material, it would not be possible to realize a light absorption as low as possible; also, after the etching treatment, the surface topography would comprise an undesirably high proportion of undersize craters. Reducing the quantity of target dopant along the sputtering line allows three—originally oppositely acting—requirements to the film to be made independent of each other. The highly doped film portion of the ZnO front electrode film, which is located adjacent the substrate of the module, provides the required low sheet resistivity, while the film portions deposited at the end of the sputtering line from low-dopant targets are highly transparent and enable the required overall low light absorption to be obtained. In the etching treatment, it is the low-dopant material which is removed predominantly, so that etching results in a more favorable surface topography than with high-dopant material.

Light trapping inside the thin-film solar cell involves the travel of long-wavelength light, in particular, through the semiconductor film several times—e.g. 5 to 20 passes in the case of a silicon semiconductor film. Most of these will take place inside the semiconductor layer as the refractive index thereof is highest; still, the dwell probability of photons will reach into the portions of the module directly adjoining the semiconductor layer so that the boundary surface between the semiconductor film and the adjoining areas may adversely affect the light trapping performance. Thus the inventive gradually decreasing dopant quantity in the front electrode film will gradually reduce the quantity of light it absorbs as fewer free charge carriers and dopant atoms capable of absorbing, photons will be present especially in the portions of the frontelectrode film that are near the semiconductor material.

Despite tight process controls, sputtered doped ZnO films tend to experience fluctuating etch rates in wet etching, resulting in a variable film thickness and in a variable sheet resistivity. These variations affect the characteristic performance data of the module. By virtue of the inventive gradual decrease of the target dopant quantity, the film portions facing the substrate of the front electrode film assume and satisfy most of the electrical requirements. For this reason, fluctuating etch rates affect the sheet resistivity to a reduced extent only so that the over-all performance characteristics of the module are less variable.

As regards the doped ZnO rear electrode film between the semiconductor film and the white reflecting layer, the invention provides that the dopant quantity in the doped ZnO rear electrode film increase from the reflecting film towards the semiconductor film, i.e. that it decrease from the semiconductor film towards the white reflecting layer. The following advantages may be obtained this way:

An optically beneficial step change in refractive indexes takes place at the boundary between the semiconductor and rear electrode films. ZnO films having a high charge carrier density tend to have a lower refractive index. In the given situation, the refractive index has to be considered in relation to the semiconductor film's; since that refractive index, which is 3.5 for a silicon semiconductor film, for example, is higher than that of zinc oxide, reflexion at the boundary between the semiconductor and rear electrode films will be the more pronounced the lower the refractive index of the rear electrode film. For this reason, a major step change in the refractive index at that boundary will result in pronounced reflexion and cause minor quantities only of light to traverse the rear electrode film, to be reflected at the white reflecting dielectric film. For these quantities of light, which are reflected at the boundary to the rear electrode film already, light absorption by double passage through the rear electrode film upon reflexion at the white layer is not relevant any longer.

Because of the damage to the semiconductor film which would take place above approx. 180° C., deposition of the rear electrode film is limited as to process temperature. Deposition should be performed at a substrate temperature not higher than 180° C., preferably not higher than 120° C. and even as low as room temperature. At temperatures so low it is in fact possible to deposit highly doped ZnO layers exhibiting good opto-electric characteristics, and especially a high mobility; the quality of lower-doped ZnO films applied at low deposition temperatures will be inferior. As a consequence, it is beneficial to start depositing the rear electrode film by applying highly doped ZnO directly onto the semiconductor film.

In further deposition, two factors are beneficial for a dopant quantity decreasing towards the white reflecting film. On the one hand, the more highly doped ZnO previously formed offers a good basis for a high-quality growth of the ZnO rear electrode film. This ensures a high opto-electric quality of the portions facing the semiconductor film of the rear electrode film, that quality being better than, for example, in the portions facing the substrate of the front electrode film, which substrate may be glass.

Also, and as described above in connection with the deposition of the front electrode film, the substrate temperature during the deposition of the rear electrode film has increased while the first and more highly doped ZnO portion was deposited so that the temperature range attained will automatically be one beneficial to a low-doped ZnO film.

Comparison of two films of the same charge carrier count and the same mobility but of different thickness and charge carrier concentration shows that the more highly doped and thinner films tends to absorb more light in the long-wavelength range, whereas the lower-doped but thicker films absorb mainly in the visible range, of the spectrum. This relationship shows that, if it is desired to provide part of the conductivity of the rear electrode film by the lower-doped portion of the ZnO film which faces the white reflecting layer, part of the light absorption should be shifted from the long-wavelength to the visible ranges of the spectrum. This is advantageous for the rear electrode film: the light absorption already effected in the semiconductor film causes reflexion at the white reflecting layer to be in the long-wavelength range.

The invention will now be explained in greater detail under reference to the attached drawing.

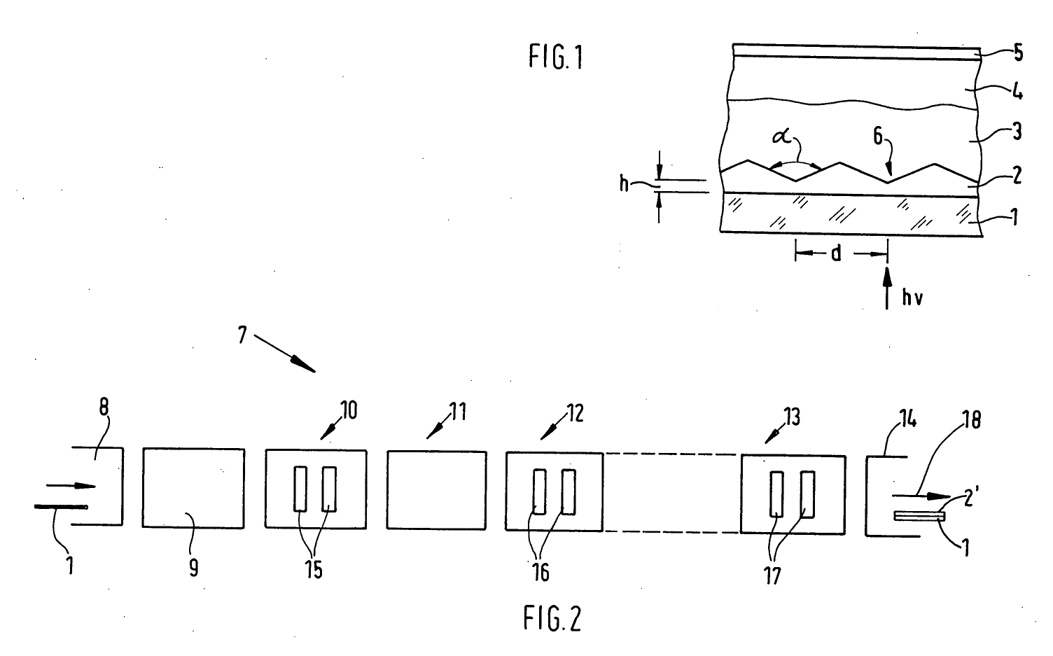

FIG. 1 is a sectional view through part of a thin-film solar module; and

FIG. 2 shows a plant for depositing the front electrode film of the thin-film solar module.

As shown in FIG. 1, the module consists of a transparent substrate 1, such as a sheet of glass, a transparent front electrode film 2 of Al-doped ZnO, for example, a semiconductor film 3 e.g. of silicon, a transparent rear electrode film 4 of Al-doped ZnO, for example, and a reflecting coating 5 of white paint, for example.

The quantity of dopant in the doped ZnO front electrode film 2 decreases from substrate 1 towards semiconductor film 3, as does the dopant quantity in the doped ZnO rear electrode film 4 from the semiconductor film 3 towards the reflecting coating 5, where it increases from reflecting coating 5 towards semiconductor film 3.

Front electrode film 2 has on its side facing the semiconductor film a texture—generated by an etching treatment—consisting of crater-shaped recesses 6 having a depth h of e.g. 150 to 400 nm, an average mutual distance d of e.g. 800 to 3000 nm and an opening angle α of e.g. 110 to 145°.

As shown in FIG. 2, deposition plant 7 comprises a feed-in zone 8 via which the substrate 1—e.g. a glass sheet—is introduced into plant 7; followed by an evacuation zone 9 having vacuum pumps fluidly connected thereto; a first sputter station 10 holding a sputter target of e.g. silicon oxinitride for sputtering a barrier layer onto glass sheet 1; a heating zone 11, which may in fact precede sputtering station 10; as well as a plurality of sputtering stations 12, 13 for sputtering the front electrode film, which may be Al₂O₃-doped ZnO, in a plurality of partial layers onto the substrate 1 carrying the barrier layer, with the Figure merely showing sputtering stations 12, 13 adjoin feed-in and discharge zones 8 and 14, respectively, of the sputtering line for applying the doped ZnO front electrode film. Sputter targets 15 to 17 of sputtering stations 15, 12 to 13 may comprise two or more tube-type cathodes.

While the ZnO target 16 of sputtering station 12 adjoining feed-in zone 8 is provided with a high quantity—e.g. 1.5 to 2.1 wt. %—of Al₂O₃ or of another foreign oxide, the dopant concentration of ZnO target 17 of the sputtering station 13 adjacent discharge zone 14—e.g. of Al₂O₃ or another foreign oxide—is lower, i.e. 0.7 to 1.1 wt. %. for example.

The substrate 1 discharged from doping plant 7 with a heavily doped ZnO film 2′, as shown by arrow 18, is then subjected to an etching treatment using dilute hydrochlorid acid, for example, in order to form in front electrode film 3 on the side of ZnO film 2′ turned away from substrate 1 the recesses 6 shown in FIG. 1. The etching treatment and all other steps for producing the thin-film solar module are carried out in continuously operating processing plants (not shown) as well.

In further processing, semiconductor film 3 may be applied by chemical vapour-phase deposition, for example. Deposition of the doped ZnO rear electrode film 4 may then be carried out in a similar deposition plant 7, where after the white reflecting layer 5 is coated onto the rear electrode film 4.

1. A thin-film solar module comprising a transparent substrate (1), a transparent front electrode film (2) of doped zinc oxide deposited on substrate (1), a semiconductor film (3) and/or a rear electrode film (4) of doped zinc oxide deposited on semiconductor film (3) and a reflecting layer (5) on the rear surface turned away from the side of light incidence (hv), characterized in that the amount of foreign atoms in the doped zinc oxide front electrode film (2) decreases from substrate (11) towards semiconductor film (3) and/or in that the amount of foreign atoms in the doped zinc oxide rear electrode film (4) decreases from semiconductor film (3) towards reflecting layer (5).

2. Thin-film solar module as in claim 1, characterized in that the amount of foreign atoms in the doped zinc oxide on a side of front electrode film (2) facing substrate (1) and/or the amount of foreign atoms in the side turned towards semiconductor film (3) of doped rear electrode film (4) is 2×10²¹ cm⁻³ maximum and is between 1×10²⁰ cm⁻³ and 1×10²¹ cm⁻³ on the side facing semiconductor film (3) of front electrode film (2) and/or the side facing reflecting layer (5) of rear electrode film (4).

3. Thin-film solar cell as in claim 1 or 2, characterized in that the foreign atom with which the zinc oxide is doped is aluminium, gallium or boron.

4. Thin-film solar cell as in claim 1, characterized in that front electrode film (2) has on the side facing semiconductor film (3) recesses (6) having a depth of 50 to 600 nm, a width of 500 to 5000 nm and an opening angle (α) of 100 to 150°.

5. Thin-film module as in any one of the preceding claims, characterized by front electrode film (2) having on the side facing semiconductor film (3) a roughness of at least 50 nm r.m.s.

6. Thin-film solar module as in any one of the preceding claims, characterized in that front electrode film (3) and/or rear electrode film (4) have/has a sheet resistivity lower than 24 ohms per square.

7. Thin-film solar module as in any one of the preceding claims, characterized in that front electrode film (2) and/or rear electrode film (4) have/has a light absorption lower than 5% at 700 nm wavelength and lower than 8% at 950 nm wavelength.

8. Thin-film solar module as in claim 1, characterized by reflecting layer (5) consisting of a white material.

9. Thin-film solar module as in claim 1, characterized by front electrode film (2) having an average film thickness of at least 400 nm and by rear electrode film (4) having an average film thickness of at least 300 nm.

10. Thin-film solar module as in any one of the preceding claims, characterized by semiconductor film (3) being silicon.

11. A method of making the thin-film solar module of claim 1, characterized in that the doped zinc oxide front electrode film (2) and/or the doped zinc oxide rear electrode film (4) are/is deposited by sputtering in a deposition plant (7).

12. Method as in claim 11, characterized in that deposition plant (7) for the sputter deposition of front electrode film (2) and/or the rear electrode film (4) has therein for each film a plurality of zinc ocide sputter targets (16, 17) doped with aluminium oxide or gallium oxide as impurity, with the zinc oxide sputter target for depositing front electrode film (2) in deposition plant (7), and/or sputter target (17) in the deposition plant for sputtering rear electrode film (4), having in sputter station (13) adjoining the feed-in zone (8) of deposition plant (7) a greater amount of foreign oxide material than the zinc oxide sputter target (17) in sputter station (13) adjoining discharge zone (14).

13. Method as in claim 12, characterized in that zinc oxide sputter target (16) in sputter station (12) facing feed-in zone (8) of deposition plant (7) for sputtering front electrode film (2) and/or rear electrode film (4) comprises said foreign atom in an amount of between 0.9 and 1.3 wt. %, and in that zinc oxide sputter target (17) in sputtering station (13) facing discharge zone (14) of deposition plant (7) for sputtering front electrode film (2) and/or rear electrode film (4) comprises said foreign atom in an amount between 0.2 and 1.5 wt. %.

14. Method as in claim 12 or 13, characterized in that, when sputtering doped zinc oxide front electrode film (2), the temperature of substrate (1) increases from room temperature in sputtering station (12) adjoining feed-in zone (8) to not more than 280° C. in sputtering station (13) adjoining discharge zone (14).

15. Method as in claim 12 or 13, characterized in that, when sputtering doped zinc oxide front electrode film (2), the temperature rises from 80° C. in sputtering station (12) adjoining feed-in zone (8) to not more than 250° C. in sputtering station (13) adjoining discharge zone (14).

16. Method as in claim 12 or 13, characterized in that, when sputtering doped zinc oxide rear electrode film (4), the temperature of the module is 240° C. maximum.

17. Method as in claim 11 for making the thin-film solar module of claim 4 or 5, characterized in that, prior to depositing semiconductor film (3), doped zinc oxide front electrode film (2) is given an etching treatment on the side turned away from substrate (1).

18. Method as in claim 11, characterized in that doped zinc oxide front electrode film (2) and/or doped zinc oxide rear electrode film (4) are/is deposited by sputtering in a deposition plant (7), with a plurality, or all, of said zinc oxide electrode partial films being deposited in sputtering stations (12, 13) using the same sputtering gas or sputtering gas mixture.
